(19) United States
(12) Patent Application Publication
(10) Pub. No.: US 2024/0426361 A1
(43) Pub. Date: Dec. 26, 2024

(54) LOW-FREQUENCY VIBRATION ISOLATION SUPERSTRUCTURE UNIT, SUPERSTRUCTURE AND SUPERSTRUCTURE DESIGN METHOD

(71) Applicant: BEIJING INSTITUTE OF SPACECRAFT SYSTEM ENGINEERING, Beijing (CN)

(72) Inventors: Hao ZHOU, Beijing (CN); Yongquan LIU, Beijing (CN); Yunhao ZHANG, Beijing (CN); Xiaoyu ZHANG, Beijing (CN); Canghai TAN, Beijing (CN); Huizhong ZENG, Beijing (CN); Linling LI, Beijing (CN); Jianzhong YANG, Beijing (CN); Hongyou CHAI, Beijing (CN)

(21) Appl. No.: 18/674,859

(22) Filed: May 25, 2024

Related U.S. Application Data
(63) Continuation of application No. PCT/CN2021/133882, filed on Nov. 29, 2021.

(30) Foreign Application Priority Data
Nov. 25, 2021 (CN) 202111413882.0

(51) Int. Cl. F16F 7/116; G06F 30/13

(52) U.S. Cl. CPC F16F 7/116; G06F 30/13; F16F 2222/06

(57) ABSTRACT

The present disclosure discloses a low-frequency vibration-isolating superstructure unit, a superstructure and a method of designing a superstructure, is capable of solving the problem that it is difficult to meet the requirements of miniaturization and lightening of vibration-isolating devices, and the problem of reduced structural rigidity and strength caused by vibration isolation. The low-frequency vibration-isolating superstructure unit includes: an outer protective structure (1), an inner mass block (2) and a bending structure (3); the outer protective structure (1) is a concave structure and one side with an opening is placed vertically; the inner mass block (2) is arranged on the side of the outer protective structure (1) close to the vertical inner wall, the inner mass block (2) is connected with the bending structure (3) only at the top close to the side with the opening of the concave structure; the bending structure (3) is arranged on the side of the outer protective structure (1) close to the opening, the bending structure (3) includes [symbol] shaped structures (18) vertically spliced, a top vertical beam (12) and a top transverse beam (13).

### TECHNICAL FIELD

The application herein relates to the technical field of vibration isolation, and in particular to a low-frequency vibration isolating superstructure unit, a superstructure and a method of designing a superstructure.

### BACKGROUND

Flat plate structures are widely used in aerospace engineering to secure various types of devices and instruments. During operation, some devices produce mechanical vibrations. These vibrations are transmitted to other payloads within the plates and shells, causing failure or destruction of sensitive loads e.g., cameras, radars, etc., severely limiting the improvement of spacecraft system performance metrics such as inter-satellite laser communication accuracy, extrasolar celestial detection accuracy, ground imaging accuracy, and the like. Therefore, there is a need to develop vibration isolation techniques for specific regions of flat plate structures to reduce the impact of vibration on load-sensitive performance.

On the one hand, since a spacecraft such as a satellite relies on a launch vehicle to launch up, the payload carried by it is limited by the rocket capacity, which necessitates the design of the vibration-isolating device to be miniaturized and lightweight; on the other hand, during launching and orbiting, the spacecraft needs to withstand shock loads brought by launch vehicles, fire works and the like, which requires the vibration-isolating device itself to have certain shock resistance; furthermore, the frequency of the vibration loads experienced by the spacecraft at different stages of operation is different, which makes it necessary to consider different working frequencies when designing the vibration-isolating device; in the meantime, due to the wide application of composite materials, variable-section flat plates and the like in aerospace engineering, its vibration mode analysis is complicated. These problems present serious challenges to design of the vibration-isolating device.

The existing vibration-isolating technology can be divided into two technical approaches of vibration-isolating devices and vibration-isolating materials. The vibration-isolating device generally has disadvantages such as a large number of parts, a high assembly precision requirement, strong system non-linearity, a large volume, and a large additional mass, and particularly in the face of the problem of vibration isolation at low frequencies, it is difficult to meet the requirements of miniaturization and lightening; the vibration-isolating material method generally provides vibration isolation through the addition of soft materials, soft structures, at the connection of the equipment, but this technical approach is less effective at low-frequency vibration isolation and also results in a significant reduction in the stiffness and strength of the whole or key parts of the spacecraft, which is easy to damage under impact load.

### SUMMARY

In order to solve the above technical problems, the present application proposes a low-frequency vibration-isolating superstructure unit, a superstructure and a method of designing a superstructure, which solve the problem that it is difficult to meet the requirements of miniaturization and lightening of vibration-isolating devices, and the problem of reduced structural rigidity and strength caused by vibration isolation.

According to a first aspect of the present application, there is provided a low-frequency vibration-isolating superstructure unit, including:
an outer protective structure, an inner mass block and a bending structure;
the outer protective structure is a concave structure and one side with an opening is placed vertically; the inner mass block and the bending structure are arranged inside a cavity defined by three inner walls and an opening of the outer protective structure; an outer wall of the outer protective structure have three surfaces, each outer wall surface has one inner wall surface corresponding thereto, the two surfaces of the outer wall parallel to each other are respectively a first outer wall surface and a second outer wall surface, when the side of the outer protective structure with the opening is placed vertically, the first outer wall surface is an upper wall surface and the second outer wall surface is a lower wall surface; an outer wall surface perpendicular to the first outer wall surface and the second outer wall surface is a third outer wall surface;
the inner mass block is arranged on the side of the outer protective structure close to the vertical inner wall, the inner mass block is connected with the bending structure at the top close to the side with the opening of the concave structure; and
the bending structure is arranged on a side of the outer protective structure close to the opening, the bending structure includes [symbol] shaped structures vertically spliced, a top vertical beam and a top transverse beam, M>1; the [symbol] shaped structure is composed of a first vertical beam and a second vertical beam of the same size, and a first transverse beam and a second transverse beam of the same size, two ends of each of the first transverse beam and the second transverse beam are respectively a head and a tail, wherein one end close to the opening side of the concave structure is a head; the first transverse beam is located below the second transverse beam, the first transverse beam is flush with both end surfaces of the second transverse beam; both the first transverse beam and the second transverse beam are straight beams with equal cross sections, and the cross sections are rectangular; the first transverse beam has a first bottom surface and a second bottom surface in a horizontal direction, and the second transverse beam has a third bottom surface and a fourth bottom surface in a horizontal direction, the first bottom surface, the second bottom surface, the third bottom surface, and the fourth bottom surface are parallel to each other; an upper bottom surface of the first vertical beam is fixed to a head of the first bottom surface of the first transverse beam, and a lower bottom surface of the first vertical beam is fixed to a head of the fourth bottom surface of the second transverse beam of another [symbol] shaped structure or connected to an edge of the bottom inner wall of the outer protective structure when the [symbol] shaped structure is the bottommost [symbol] shaped structure; a lower bottom surface of the second vertical beam is fixed to a tail of the first bottom surface of the first transverse beam; an upper bottom surface of the second vertical beam is fixed to a tail of the third bottom surface of the second transverse beam; a lower bottom surface of the top vertical beam is fixed to a head of the fourth bottom surface of the second transverse beam of a top [symbol] shaped structure, and an upper bottom surface of the top vertical beam is fixed to a head of a lower bottom surface of the top transverse beam; the top transverse beam extends to the inside of the outer protective structure and is connected to the top of the inner mass block, the upper bottom surface of the top transverse beam is aligned with the top of the inner mass block.

Preferably, the bottom surface of the superstructure unit is rectangular, and a side perpendicular to the plane of the opening is a long side, and a side parallel to the plane of the opening is a short side; the superstructure unit constructs a right-hand Cartesian coordinate system with a vertex in the rectangular bottom surface away from the opening side as an origin, with a length direction of a short side of the bottom surface across the origin as an X-axis direction, with a length direction of a long side of the bottom surface across the origin as a Y-axis direction, and with a length direction of a third side across the origin point as a Z-axis direction; the superstructure unit has a thickness H₀, each outer wall surface has a length L_{w}, the distance between the corresponding inner wall surface and the outer wall surface of each group is Lₜ; a gap of the inner mass block with the inner wall surface of the outer protective structure is L_{g}, a length of the inner mass block along the y-axis direction is (L_{w}−Lₜ−2L_{g})/2, a length along the z-axis direction is L_{w}−2Lₜ−2L_{g}; the length of each of the first vertical beam, the second vertical beam and the top vertical beam in the [symbol] -shaped structure is (L_{w}−2Lₜ−L_{g})/(4M+2) along the y-axis and z-axis, the length of each of the first transverse beam and the second transverse beam in the [symbol] shaped structure 18 is (L_{w}−Lₜ−2L_{g})/2 along the y-axis and the length is (L_{w}−2Lₜ−L_{g})/(4M+2) along the z-axis, and the length of the top transverse beam is (L_{w}−Lₜ)/2 along the y-axis and the length is (L_{w}−2Lₜ−L_{g})/(4M+2) along the z-axis.

Preferably, a rectangular channel is provided between the corresponding inner wall surface and the outer wall surface of each group, four surfaces of the rectangular channel form an outer protective structural wall with an outer adjacent surface thereof, and the thickness of the outer protective structural wall is L_{g}.

According to a second aspect of the present application, there is provided a low-frequency vibration-isolating superstructure including the N superstructure units mentioned above, the N superstructure units are disposed on one side of a flat plate; the flat plate is divided into a protection region and a vibration source region according to actual operating conditions, and the region other than the protection region of the flat plate is the vibration source region; if the protection region is circular, the circumference outside the protection region is a circular boundary; otherwise, the protection region is fitted to a polygon, a minimum covering circle of the protection region that is able to cover a set of points S is determined, wherein the set of points S is a set of vertices of the polygon after the protection region is fitted, and the circumference of the minimum covering circle is the circular boundary; a radius to which the circular boundary corresponds is a protection region radius R; the N superstructure units enclose the protection region, a first short side of the second outer wall surface of each superstructure unit is parallel to a tangent to a point on the circular boundary of the protection region closest to the first short side, the first short side is a short side of the second outer wall surface of the superstructure unit close to the opening side; the distance of the first short side of each superstructure unit to the circle center of the circular boundary is greater than or equal to R; the distance of the short side of the second outer wall surface of each superstructure unit away from the opening side to the circle center of the circular boundary is greater than the distance of the first short side to the circle center of the circular boundary; the N superstructure units are N uniformly sized superstructure units, N>1.

Preferably, after arranging N superstructure units around the protection region, the N superstructure units form a circular closed region on the flat plate, the closed region is composed of connecting lines of the centers of the second outer wall surfaces of the outer protective structures in the superstructure units in a counterclockwise or clockwise direction, wherein the connecting line is a circular arc; the radius R of the protection region is smaller than the radius Rₘ of the closed region.

Preferably, a planar polar coordinate system is constructed by taking the circle center of the circular boundary of the protection region as the pole point and taking any direction as the polar axis, and the position of each superstructure unit is represented by the bottom surface center point, the position of the superstructure unit is uniquely determined by Rₘ and θᵢ, 1≤i≤N; Rₘ represents the radius of the closed region enclosed by the center points of the bottom surfaces of the superstructure units, and the value of the radius is determined based on the radius R of the protection region and the long-side size of the second outer wall surface; θ₁ represents the polar angle of the center point of the bottom surface of the first superstructure unit on a circle of radius Rₘ, and remaining polar angles θᵢ represent the angles between the ith superstructure unit and the i−1th superstructure unit; the value of θᵢ is determined according to the principle of maximization of vibration isolation efficiency; the first superstructure unit is any one of the N superstructure units, and the remaining superstructure units are sequentially numbered in a clockwise direction, or sequentially numbered in a counterclockwise direction from the first superstructure unit.

Preferably, in the superstructure, the second outer wall surface of the outer protective structure of the superstructure unit is fixed directly to the surface of the flat plate, and a contact part between the second outer wall surface and the flat plate does not move relatively.

According to a third aspect of the present application, there is provided a method of designing a low-frequency vibration-isolating superstructure, the low-frequency vibration-isolating superstructure is the low-frequency vibration-isolating superstructure mentioned above, and the method includes the following steps:
Step S1: acquiring a frequency f of external vibration that needs to be isolated, a first order natural frequency f₁ of a superstructure unit; disposing a superstructure on one side of a flat plate, denoting the length, width and height of the flat plate as Lₚₕ, L_{pw}, Lₚₜ, respectively; denoting the material density, Young's modulus and Poisson's ratio of the flat plate as ρ_{b}, E_{b} and μ_{b}, respectively; making a circular boundary of a protection region of the low-frequency vibration-isolating superstructure a circle of radius R; denoting the material density, Young's modulus and Poisson's ratio of the superstructure unit as ρ, E and μ, respectively;
Step S2: obtaining defining conditions for the volume of the low-frequency vibration-isolating superstructure, determining a minimum value L_{w}^{min} and a maximum value L_{w}^{max} of L_{w} based on the defining conditions, initializing L_{w} into (L_{w}^{min}+L_{w}^{max})/2, determining initial values of Lₜ and L_{g} such that the initial values satisfy the following inequalities:

$$\{ \begin{matrix}0 < {L}_{g} < {L}_{t} / 2 \\ {L}_{t} < ( {L}_{w} - 2 {L}_{g} ) / 2\end{matrix}$$

initializing H₀, such that 0<H₀<L_{w}/2; initializing the value of M to 1;
Step S3: based on the initial values of the structural parameters L_{w}, Lₜ, L_{g}, H₀, M and the material parameters of the superstructure unit, establishing a finite element model of the superstructure unit, setting a second outer wall surface of the superstructure unit as a fixed boundary condition; optimizing the parameters L_{w}, Lₜ, the optimized parameters L_{w}, Lₜ making the first order natural frequency f₁ of the superstructure unit equal to f;
Step S4: modifying the superstructure unit based on the optimized parameters L_{w}, Lₜ, performing intensity checking on the superstructure unit;
Step S5: acquiring size parameters and material parameters of the flat plate of the low-frequency vibration-isolating superstructure, establishing a finite element model according to the size and material parameters, setting several vibration sources according to actual operating conditions at a vibration source region, and applying an excitation force with a frequency f to simulate an actual vibration source; making the radius of the closed circular region defined by the center points of the bottom surfaces of the low-frequency vibration-isolating superstructure units Rₘ, which is greater than or equal to R+L_{w}/2; initializing a number N of the superstructure units, N satisfying Nₘᵢₙ≤N≤Nₘₐₓ, wherein N, Nₘᵢₙ and Nₘₐₓ are all positive integers; taking an initial value of N as Nₘᵢₙ; the lower limit of Nₘᵢₙ being 3; the upper limit of Nₘₐₓ being

$$[ \frac{π}{arc tan ( \frac{{H}_{0}}{2 {R}_{m} - {L}_{w}} )} ] ,$$

[ ] representing a rounding function;
Step S6: setting several vibration sources according to actual operating conditions in the vibration source region, and applying an excitation force with a frequency f; arranging the N modified superstructure units into a circular closed region of radius Rₘ taking the center points of the bottom surfaces as the reference points; making the first superstructure unit on a connecting line of either vibration source and the circle center by the initial value of θ₁; making all the superstructure units evenly distributed over the boundary of the closed region of radius Rₘ by the initial values of the remaining polar angles θᵢ;
Step S7: calculating a variable η=|w/w₀| by traversing all positive integers in the interval [Nₘᵢₙ, Nₘₐₓ], finding the value of N that minimizes η; wherein w represents an average out-of-plane displacement of the protection region when the flat plate has the superstructure units, w₀ represents the average out-of-plane displacement of the protection region when the flat plate has no superstructure units;
Step S8: if N=Nₘₐₓ, making Nₘᵢₙ=[Nₘᵢₙ+Nₘₐₓ/2], Nₘₐₓ=[3Nₘₐₓ−Nₘᵢₙ/2], proceeding to Step S7; and
if N<Nₘₐₓ, proceeding to step S9; [ ] denoting a rounding function; and
Step S9: determining position angles θᵢ, of the N superstructure units, 1<i<N, wherein: θ₁ has an optimization interval of [0°, 360°], θ₂˜θ_{N} have an optimization interval of

$$[ 2 atan ( \frac{{H}_{0}}{2 R - {L}_{w}} ) , 360 ° - 2 N atan ( \frac{{H}_{0}}{2 R - {L}_{w}} ) ] ,$$

the constraint condition is

$${\sum }_{i = 2}^{N} {θ}_{i} \leq 360 ° - 2 atan ( \frac{{H}_{0}}{2 R - {L}_{w}} ) ,$$

and the optimization objective is to minimize the variable η.

Preferably, the step S3 of optimizing the parameters L_{w}, Lₜ, the optimized parameters L_{w}, Lₜ making the first order natural frequency f₁ of the superstructure unit equal to f includes:
Step S301: determining an optimization interval of the parameter L_{w} as [L_{w}^{min},L_{w}^{max}], the optimization objective being to minimize obj=(f₁−f²); determining the initial values of L_{w}^{min}, L_{w}^{max} according to the operating conditions;
Step S302: if the obtained parameter L_{w} after optimization is equal to L_{w}^{max} then setting M to M+1, proceeding to Step S301; if the obtained parameter L_{w} after optimization is equal to L_{w}^{min}, re-determining Lₜ, L_{g} and H₀, satisfying the following inequalities:

$$\{ \begin{matrix}0 < {L}_{g} < {L}_{t} / 2 \\ {L}_{t} < ( {L}_{w} - 2 {L}_{g} ) / 2\end{matrix} \\ 0 < {H}_{0} < {L}_{w} / 2$$

proceeding to step S301;
if the obtained parameter L_{w} after optimization satisfies L_{w}∈(L_{w}^{min}, L_{w}^{max}), updating the parameter L_{w} to the value of the optimized parameter L_{w}, proceeding to step S303; and
Step S303: determining an optimization interval of the parameter Lₜ as [2L_{g}, (L_{w}−2L_{g})/2], excluding endpoint values here; the optimization objective being to minimize obj=(f₁−f)², updating the parameter Lₜ to the value of the optimized parameter Lₜ.

Preferably, in the step S5, the initial value of Nₘᵢₙ is taken to be 3 and the initial value of Nₘₐₓ is taken to be

$$[ \frac{π}{6 arc tan ( \frac{{H}_{0}}{2 {R}_{m} - {L}_{w}} )} ] .$$

### Advantageous Effects

(1) The superstructure unit is designed based on the resonance principle, and the superstructure unit can obtain an extremely large equivalent density with an extremely small geometric size, thereby realizing total reflection of bending waves in a flat plate, and solving the problem that the vibration-isolating device is large in volume and large in additional mass; the influence of the material and structural parameters of the flat plate on the vibration isolation effect is avoided. By designing the bending mode of the [symbol] shaped structure, the equivalent stiffness of the superstructure unit can be greatly varied, resulting in superstructure units for different operating frequencies. Movement of an internal oscillator structure is limited by the outer protective structure, thereby protecting the vibration-isolating superstructure from damage under impact loading; the superstructure unit is integrally formed of a metallic material and is attached directly to the flat plate without detracting from the overall stiffness of the spacecraft, making the spacecraft safer under impact loading.

The outer protective structure serves to limit the movement of the inner mass block, thus protecting the inner mass block and the bending structure from damage under impact loading; the inner mass block is equivalently an oscillator for adjusting the first order natural frequency of the superstructure unit, and the bending structure is equivalently a spring for adjusting the first order natural frequency of the superstructure unit.

The outer protective structure, the inner mass block and the bending structure are connected in such a way that the inner space of the outer protective structure is fully utilized, so that the superstructure unit formed thereof is more compact and small; the inner mass block and the bending structure are located entirely inside the outer protective structure, and their movement is limited by the outer protective structure, thereby protecting them from damage under resonance and impact loading; the superstructure unit is secured directly to the flat plate by the second outer wall surface of the outer protective structure without diminishing the stiffness and load bearing capacity of the flat plate, and the flat plate is not easy to destroy under the impact loading and is safer.
(2) The first order natural angular frequency ω₁ of the superstructure unit can be varied by setting the sizes of the respective components of the superstructure unit, thereby obtaining a superstructure unit whose equivalent density tends to infinity, and further causing its equivalent bending degree and torsional stiffness to tend to infinity to isolate elastic waves.
(3) Rectangular channels can reduce the mass of the superstructure unit, making it more lightweight.
(4) The vibration-isolating superstructure is formed by arranging a plurality of low frequency vibration-isolating superstructure units on the flat plate to form a closed region, and the vibration isolation in a local region is realized. This allows the superstructure to be applied to different flat plate structures such as composite materials, variable section flat plates and the like.
(5) A plurality of superstructure units are arranged into a circular closed region which can protect an arbitrary shape protection region; at the same time, the structure of the circular closed region is simple, which simplifies the subsequent determination of the location of the superstructure unit and its optimization.
(6) the overall position is uniquely determined by the absolute position θ₁ of the first superstructure unit on the circle and the relative positions θᵢ of the other units. Further, the superstructure vibration isolation effect is enhanced by optimization of the position variables θ₁ and θᵢ of the superstructure units.
(7) According to the solution of the present application, the direct fixing of the superstructure unit on the surface of the flat plate avoids damage to the rigidity and load-bearing capacity of the flat plate; the second outer wall surface is fixed directly to the surface of the flat plate so that the outer protective structure of the superstructure unit does not move during first order resonance, and only the inner mass block and the bending structure are moved, thereby providing protection to the inner mass block and the bending structure.
(8) When the parameters such as the material and thickness of the flat plate structure are changed, the vibration-isolating superstructure designed by optimization can play a role.
(9) According to the solution of the present application, further optimization of Lₜ on the basis of optimization of the parameter L_{w} makes it possible to bring the optimization objective obj=(f₁−f)² closer to zero, i.e. a superstructure unit with a first order natural frequency f₁ closer to the target frequency f is obtained.
(10) According to the solution of the present application, the initial values of Nₘᵢₙ and Nₘₐₓ are selected to reduce the interval range at the initial optimization, reduce the time required for the initial optimization, and improve the optimization efficiency; in addition, a smaller initial value makes the number N of the superstructure units optimized smaller, while reducing the number of the superstructure units makes the added mass of the flat plate less, allowing a lightweight design.

The above description is only an overview of the technical solutions of the present application. In order to have a clearer understanding of the technical means of the present application and make the technical means implemented according to the contents of the specification, the preferred embodiments of the present application are described in detail below with the accompanying drawings.

### BRIEF DESCRIPTION OF FIGURES

The accompanying drawings, which form a part of this application, are included to provide a further understanding of the application, and the application is described below with reference to the accompanying drawings. In the drawings:

FIG. 1 (A) is a structural schematic diagram of a superstructure unit according to a first embodiment of the present application;

FIG. 1 (B) is a structural schematic diagram of a superstructure unit according to a second embodiment of the present application;

FIG. 1 (C) is an enlarged partial view of a bending structure of the present application;

FIG. 2 is a transmissivity density distribution diagram of the present application;

FIG. 3 is a schematic diagram of an equivalent two degree of freedom spring-mass system of a superstructure unit of the present application;

FIG. 4 is a schematic diagram of a variation curve of an equivalent density with a frequency ratio of the present application;

FIG. 5 (A) is a structural schematic diagram of a low-frequency vibration-isolating superstructure of the present application;

FIG. 5 (B) is a structural top view of a low-frequency vibration-isolating superstructure of the present application;

FIG. 5 (C) is a position relationship diagram of each region of a flat plate of the present application;

FIG. 5 (D) is a schematic diagram of the position distribution of a low-frequency vibration-isolating superstructure unit of the present application;

FIG. 6 (A) is a schematic diagram of the first-order mode of the vibration-isolating superstructure unit of a third embodiment;

FIG. 6 (B) is a schematic diagram of the first-order mode of the vibration-isolating superstructure unit of a fourth embodiment;

FIG. 7 is a schematic diagram of a curve of parameters changing with the number of superstructure units;

FIG. 8 (A) is a schematic diagram of an out-of-plane displacement amplitude field of an optimized flat plate without superstructure units of a fifth embodiment;

FIG. 8 (B) is a schematic diagram of an out-of-plane displacement amplitude field of an optimized flat plate with superstructure units of a fifth embodiment;

FIG. 9 (A) is a schematic diagram of an out-of-plane displacement amplitude field of an optimized flat plate without superstructure units of a sixth embodiment and

FIG. 9 (B) is a schematic diagram of an out-of-plane displacement amplitude field of an optimized flat plate with superstructure units of a sixth embodiment.

### REFERENCE SIGNS

1, outer protective structure; 2, inner mass block; 3, bending structure; 4, flat plate; 5, superstructure unit; 6, protection region; 7, vibration source region; 8, first vertical beam; 9, second vertical beam; 10, first transverse beam; 11, second transverse beam; 12, top vertical beam; 13, top transverse beam; 14, first bottom surface; 15, second bottom surface; 16, third bottom surface; 17, fourth bottom surface; 18, [symbol] shaped structure.

### DETAILED DESCRIPTION

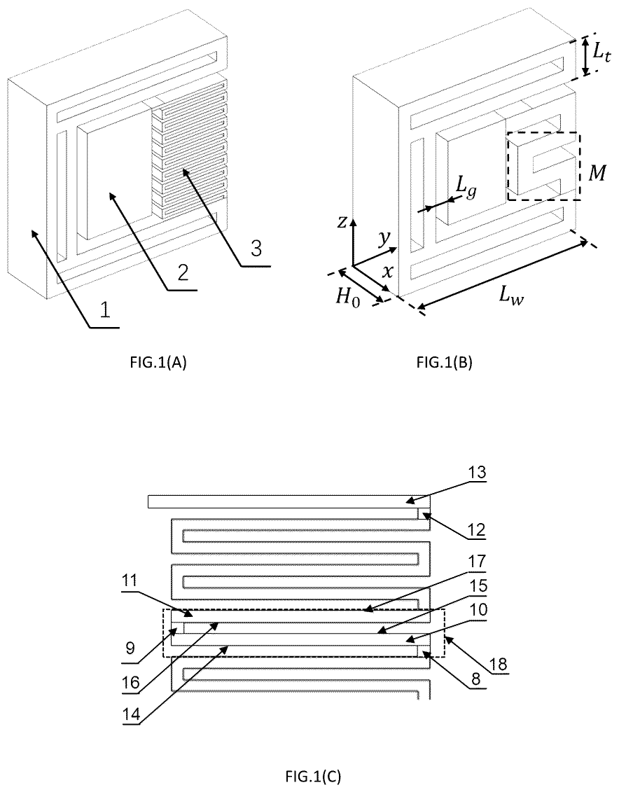

In accordance with a first aspect of the present application, a low-frequency vibration-isolating superstructure according to one embodiment of the present application is first described with reference to FIGS. 1 (A)-1 (C). The low-frequency vibration-isolating superstructure unit, including:
an outer protective structure 1, an inner mass block 2 and a bending structure 3;
the outer protective structure 1 is a concave structure and one side with an opening is placed vertically; the inner mass block 2 and the bending structure 3 are arranged inside a cavity defined by three inner walls and an opening of the outer protective structure 1; an outer wall of the outer protective structure 1 have three surfaces, each outer wall surface has one inner wall surface corresponding thereto, the two surfaces of the outer wall parallel to each other are respectively a first outer wall surface and a second outer wall surface, when the side of the outer protective structure 1 with the opening is placed vertically, the first outer wall surface is an upper wall surface and the second outer wall surface is a lower wall surface; an outer wall surface perpendicular to the first outer wall surface and the second outer wall surface is a third outer wall surface;
the inner mass block 2 is arranged on the side of the outer protective structure 1 close to the vertical inner wall, the inner mass block 2 is connected with the bending structure 3 at the top close to the side with the opening of the concave structure; and
the bending structure 3 is arranged on a side of the outer protective structure 1 close to the opening, the bending structure 3 includes [symbol] shaped structures 18 vertically spliced, a top vertical beam 12 and a top transverse beam 13, M>1; the [symbol] shaped structure 18 is composed of a first vertical beam 8 and a second vertical beam 9 of the same size, and a first transverse beam 10 and a second transverse beam 11 of the same size, two ends of each of the first transverse beam 10 and the second transverse beam 11 are respectively a head and a tail, wherein one end close to the opening side of the concave structure is a head; the first transverse beam 10 is located below the second transverse beam 11, the first transverse beam 10 is flush with both end surfaces of the second transverse beam 11; both the first transverse beam 10 and the second transverse beam 11 are straight beams with equal cross sections, and the cross sections are rectangular; the first transverse beam 10 has a first bottom surface 14 and a second bottom surface 15 in a horizontal direction, and the second transverse beam 11 has a third bottom surface 16 and a fourth bottom surface 17 in a horizontal direction, the first bottom surface 14, the second bottom surface 15, the third bottom surface 16, and the fourth bottom surface 17 are parallel to each other; an upper bottom surface of the first vertical beam 8 is fixed to a head of the first bottom surface 14 of the first transverse beam 10, and a lower bottom surface of the first vertical beam 8 is fixed to a head of the fourth bottom surface 17 of the second transverse beam 11 of another [symbol] shaped structure or connected to an edge of the bottom inner wall of the outer protective structure 1 when the [symbol] shaped structure is the bottommost [symbol] shaped structure; a lower bottom surface of the second vertical beam 9 is fixed to a tail of the first bottom surface 15 of the first transverse beam 10; an upper bottom surface of the second vertical beam 9 is fixed to a tail of the third bottom surface 16 of the second transverse beam 11; a lower bottom surface of the top vertical beam 12 is fixed to a head of the fourth bottom surface 17 of the second transverse beam 11 of a top [symbol] shaped structure, and an upper bottom surface of the top vertical beam 12 is fixed to a head of a lower bottom surface of the top transverse beam 13; the top transverse beam 13 extends to the inside of the outer protective structure 1 and is connected to the top of the inner mass block 2, the upper bottom surface of the top transverse beam 13 is aligned with the top of the inner mass block 2.

Further, the bottom surface of the superstructure unit 5 is rectangular, and a side perpendicular to the plane of the opening is a long side, and a side parallel to the plane of the opening is a short side; the superstructure unit 5 constructs a right-hand Cartesian coordinate system with a vertex in the rectangular bottom surface away from the opening side as an origin, with a length direction of a short side of the bottom surface across the origin as an X-axis direction, with a length direction of a long side of the bottom surface across the origin as a Y-axis direction, and with a length direction of a third side across the origin point as a Z-axis direction; the superstructure unit 5 has a thickness H₀, each outer wall surface has a length L_{w}, the distance between the corresponding inner wall surface and the outer wall surface of each group is Lₜ; a rectangular channel is provided between the corresponding inner wall surface and the outer wall surface of each group, the rectangular channels can reduce the mass of superstructure units and make them lighter. Four surfaces of the rectangular channel form an outer protective structural wall with an outer adjacent surface thereof, and the thickness of the outer protective structural wall is L_{g}. A gap of the inner mass block 2 with the inner wall surface of the outer protective structure is L_{g}, a length of the inner mass block 2 along the y-axis direction is (L_{w}−Lₜ−2L_{g})/2, a length along the z-axis direction is L_{w}−2Lₜ−2L_{g}; the length of each of the first vertical beam, the second vertical beam and the top vertical beam in the [symbol] shaped structure 18 is (L_{w}−2Lₜ−L_{g})/(4M+2) along the y-axis and z-axis, the length of each of the first transverse beam and the second transverse beam in the [symbol] shaped structure 18 is (L_{w}−Lₜ−2L_{g})/2 along the y-axis and the length is (L_{w}−2Lₜ−L_{g})/(4M+2) along the z-axis, and the length of the top transverse beam is (L_{w}−Lₜ)/2 along the y-axis and the length is (L_{w}−2Lₜ−L_{g})/(4M+2) along the z-axis.

The principle of structural construction and size design of the superstructure unit 5 will now be described. The principle that the superstructure unit 5 can function as frequency-specific vibration isolation in the plate is:
based on the wave equation of the plate, the transmissivity amplitude of the bending wave in the plate with the superstructure units is derived by the equivalent parameter method as shown in Equation 1:

$$\vert t \vert = \vert \frac{i ( 1 + α - β )}{( i + α + α i ) ( 1 - β - β i )} \vert \qquad ( Equation 1 )$$

wherein,

$$α = \frac{ρ A {ω}^{2}}{4 D \text{?}}$$

$$\text{?} \text{indicates text missing or illegible when filed}$$

denotes the equivalent bending dynamic stiffness of the superstructure unit 5,

$$β = \frac{ρ \text{?} {ω}^{2}}{4 Dk}$$

$$\text{?} \text{indicates text missing or illegible when filed}$$

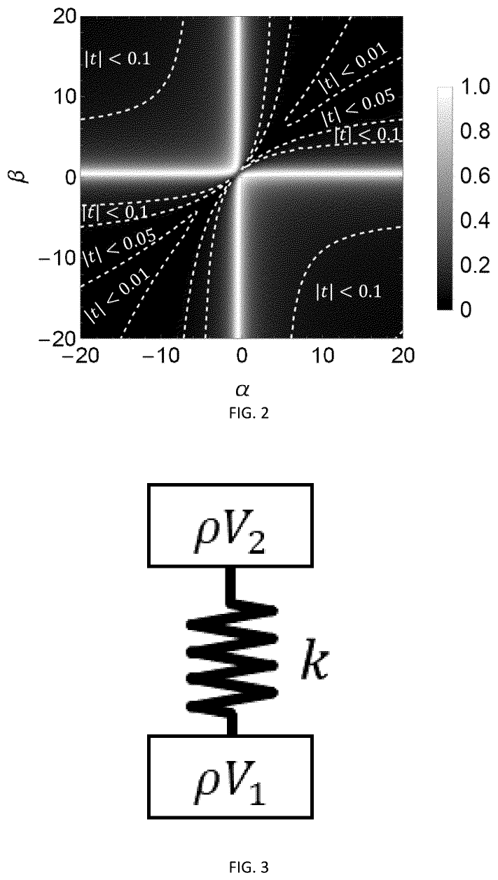

denotes the equivalent torsional dynamic stiffness of the superstructure unit 5, ρ denotes the material density of the superstructure unit 5, A denotes the cross-sectional area of the superstructure unit 5, J denotes the polar moment of inertia of the superstructure unit 5 to the center of rotation of the plane in the plate, ω denotes the angular frequency of the bending wave, D denotes the bending stiffness of the plate, and k denotes the wave number of the bending wave in the plate. From the density distribution diagram of the transmissivity amplitude shown in FIG. 2, which reflects the transmissivity amplitude of Equation 1, it can be obtained that the bending wave transmissivity decreases to a very low level as α and β tend to be large both positive and negative. The protection region 6 has an amplitude of less than 0.1 and an energy of less than 0.01, meaning that more than 99% of the energy can be bounced back by the superstructure unit 5. Thus, total reflection of bending waves can be achieved by adding superstructure units 5 to the plate 4, and further enclosing the superstructure units 5 into a closed shape to form the superstructure can achieve vibration isolation to a local region of the plate 4. At the same time, the direct addition of the superstructure units 5 on the plate 4 avoids the secondary design of a complex vibration-isolating device, reduces the number of parts, reduces assembly accuracy requirements and system non-linearity.

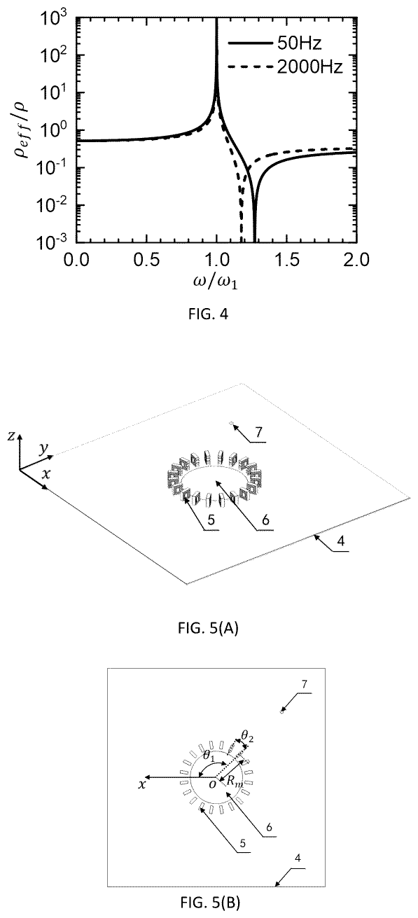

The superstructure unit 5 can be simplified to a two degree of freedom spring-mass system as shown in FIG. 3. Wherein, ρ denotes the material density of the superstructure unit 5, V₁ and V₂ denote the volumes of the outer protective structure 1 and the inner mass block 2, respectively, and k denotes the equivalent stiffness of the bending structure. The equivalent density of the superstructure unit 5 can be obtained from vibration theory as shown in Equation 2:

$$\frac{{ρ}_{eff}}{ρ} = ( \frac{{V}_{1}}{{V}_{eff}} + \frac{{V}_{2} / {V}_{eff}}{( 1 - {( ω / {ω}_{1} )}^{2} )} ) \qquad ( Equation 2 )$$

wherein, ρ_{eff} denotes the equivalent density of the superstructure unit, V_{eff} denotes the equivalent volume of the superstructure unit 5, and is taken as a rectangular block volume equal to the length, width and height of the outer protective structure 1 of the superstructure unit after optimization, i.e. V_{eff}=L_{w}×L_{w}×H₀, ω denotes the bending wave angular frequency, and ω₁ denotes the natural angular frequency of the inner mass block 2 and the bending structure 3. A variation curve of an equivalent density (ρ_{eff}/ρ) obtained by Equation 2 with a frequency ratio (ω/ω₁) is shown in FIG. 4, which is shown in this embodiment for 50 Hz and 2000 Hz, respectively. When the natural angular frequency of the inner mass block 2 and the bending structure 3 is equal to the bending wave angular frequency, i.e. resonance occurs, the equivalent density of the superstructure unit 5 tends to infinity, as the α and β of the superstructure unit 5 are related to the equivalent density, they also tend to infinity. Thus, the resonance-based superstructure unit 5 enables total elastic wave reflection, while ω₁ can be varied by designing the five variables L_{w}, Lₜ, L_{g}, M and H₀ to obtain a resonant unit at a specific frequency.

The variation of the equivalent stiffness can be achieved by setting the number M of the [symbol] shaped structures 18, as the larger M, i.e. the more [symbol] shaped structures 18, the smaller the equivalent stiffness of the bending structure 3. The bending structure 3 enables the superstructure unit 5 to achieve a lower resonance frequency without reducing the stiffness and strength of the material itself, and makes the superstructure unit 5 more compact and smaller. The [symbol] shaped structures 18 of different sizes or different numbers can be equivalent to different stiffnesses k, resulting in different first order natural frequencies. Of course, the first order natural frequency depends not only on the bending structure 3, but also on the mass of the inner mass block 2, which is related to L_{w}, Lₜ, L_{g} and H₀.

In the solution of the present embodiment, the superstructure unit 5 is designed based on the resonance principle, and the superstructure unit 5 can obtain a great equivalent density with a very small geometric size, thereby realizing total reflection of bending waves in the flat plate 4, and solving the problem of the large volume and large additional mass of the vibration-isolating device; the influence of the material and structural parameters of the flat plate 4 on the vibration isolation effect is avoided. By designing the bending mode of the [symbol] shaped structure 18, the equivalent stiffness of the superstructure unit 5 can be greatly varied, resulting in superstructure units 5 for different operating frequencies. The movement of the internal oscillator structure is limited by the outer protective structure 1, thereby protecting the vibration-isolating superstructure from breaking under impact loading; the superstructure unit 5 is integrally made of a metallic material and is attached directly to the flat plate, without detracting from the overall stiffness of the spacecraft, thus making the spacecraft safer under impact loading.

The outer protective structure 1 serves to limit the movement of the inner mass block 2, thus protecting the inner mass block 2 and the bending structure 3 from damage under resonance and impact loading; the inner mass block 2 is equivalently an oscillator for adjusting the first order natural frequency of the superstructure unit, and the bending structure 3 is equivalently a spring for adjusting the first order natural frequency of the superstructure unit.

The first order natural angular frequency ω₁ of the superstructure unit 5 can be varied by setting the sizes of the respective components of the superstructure unit 5, thereby obtaining a superstructure unit 5 whose equivalent density tends to infinity, and further causing its equivalent bending degree and torsional stiffness to tend to infinity to isolate elastic waves.

The outer protective structure 1, the inner mass block 2 and the bending structure 3 are connected in such a way that the inner space of the outer protective structure 1 is fully utilized, so that the superstructure unit 5 formed thereof is more compact and small; the inner mass block 2 and the bending structure 3 are located entirely inside the outer protective structure 1, and their movement is limited by the outer protective structure 1, thereby protecting them from damage under impact loading; the superstructure unit 5 is secured directly to the flat plate by the second outer wall surface of the outer protective structure 1 without diminishing the stiffness and load bearing capacity of the flat plate 4, and the flat plate is not easy to destroy under the impact loading and is safer.

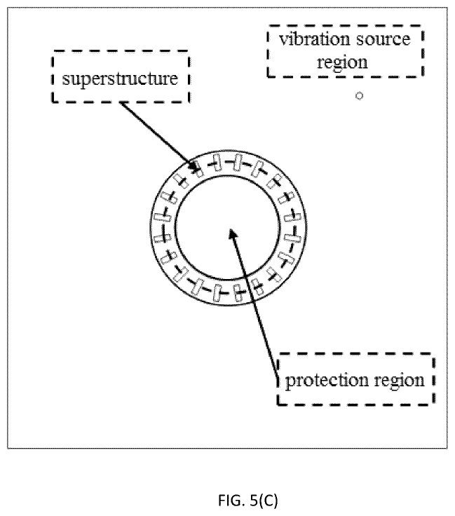

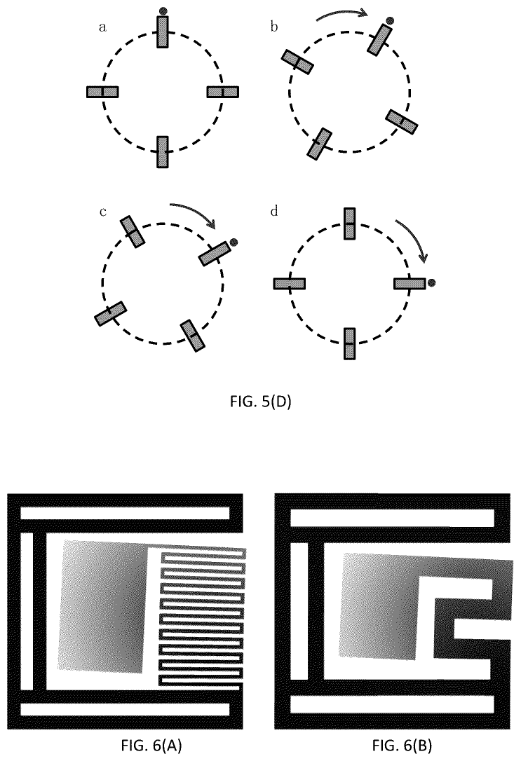

According to a second aspect of the present application, a low-frequency vibration-isolating superstructure is illustrated according to an embodiment of the present application, as shown in FIG. 5(A), the low-frequency vibration-isolating superstructure includes N superstructure units 5, the N superstructure units 5 are disposed on one side of a flat plate 4; the flat plate 4 is divided into a protection region 6 and a vibration source region 7 according to actual operating conditions, and the region other than the protection region 6 of the flat plate 4 is the vibration source region 7; if the protection region 6 is circular, the circumference outside the protection region is a circular boundary; otherwise, the protection region is fitted to a polygon, a minimum covering circle of the protection region 6 that is able to cover a set of points S is determined, wherein the set of points S is a set of vertices of the polygon after the protection region 6 is fitted, and the circumference of the minimum covering circle is the circular boundary; a radius to which the circular boundary corresponds is a protection region radius R; the N superstructure units enclose the protection region 6, a first short side of the second outer wall surface of each superstructure unit 5 is parallel to a tangent to a point on the circular boundary of the protection region 6 closest to the first short side, the first short side is a short side of the second outer wall surface of the superstructure unit close to the opening side; the distance of the first short side of each superstructure unit 5 to the circle center of the circular boundary is greater than or equal to R; the distance of the short side of the second outer wall surface of each superstructure unit 5 away from the opening side to the circle center of the circular boundary is greater than the distance of the first short side to the circle center of the circular boundary; the N superstructure units 5 are N uniformly sized superstructure units, N>1.

In this embodiment, the region to be protected on the flat plate 4 is determined by actual conditions, and then N superstructure units 5 are arranged according to the region to be protected. If the protection region 6 is circular, the radius of the protection region 6 is denoted as R, the circumference outside this protection region 6 is a circular boundary; otherwise, the protection region 6 is fitted to a polygon, a minimum covering circle of the protection region 6 that is able to cover a set of points S is determined, and the radius of the minimum covering circle is denoted as R, wherein the set of points S is the set of vertices of the polygon of the protection region, and the circumference of the minimum covering circle is the circular boundary; the minimum coverage circle is calculated using algorithms known in the art, e.g., Megiddo's algorithm, Welzl's algorithm. The number of the superstructure units 5 is N, the value of which is determined according to the principle of maximizing the vibration isolation efficiency, which is a principle widely used in the art, and its purpose is to improve the isolation efficiency, but the difference is only that the quantitative description of the vibration isolation efficiency is different by different persons. In this embodiment, the isolation efficiency refers to the ratio of the average amplitudes of the protection region in the presence of the superstructure and in the absence of the superstructure. The greater the ratio, the greater the vibration isolation efficiency, and the better the vibration isolation efficiency of the superstructure.

As shown in FIG. 5 (C), after arranging N superstructure units 5 around the protection region 6, the N superstructure units 5 form a circular closed region on the flat plate 4, the closed region is composed of connecting lines of the centers of the second outer wall surfaces of the outer protective structures 1 in the superstructure units 5 in a counterclockwise or clockwise direction, wherein the connecting line is a circular arc. The protection region 6 is different from the closed region enclosed by the superstructure units 5, the radius R of the protection region is smaller than the radius Rₘ of the closed region.

The N superstructure units 5 are distributed around the protection region 6, as shown in FIG. 5 (B), a planar polar coordinate system is constructed by taking the circle center of the protection region 6 and/or the center of the minimum coverage circle as the pole point, i.e., the circle center of the circular boundary of the protection region 6 as the pole point and taking any direction as the polar axis, the position of each superstructure unit 5 is represented by the bottom surface center point, the position of the superstructure unit 5 is uniquely determined by Rₘ and θᵢ, 1≤i≤N; Rₘ represents the radius of the closed region enclosed by the center points of the bottom surfaces of the superstructure units 5, and the value of the radius is determined based on the radius R of the protection region and the long-side size of the second outer wall surface; θ₁ represents the polar angle of the center point of the bottom surface of the first superstructure unit on a circle of radius Rₘ, and remaining polar angles θᵢ represent the angles between the ith superstructure unit and the i−1th superstructure unit; the value of θᵢ is determined according to the principle of maximization of vibration isolation efficiency; the first superstructure unit is any one of the N superstructure units 5, and the remaining superstructure units are sequentially numbered in a clockwise direction, or sequentially numbered in a counterclockwise direction from the first superstructure unit.

In this embodiment, the protection region 6 is different from the closed region enclosed by the superstructure units 5, and the radius Rₘ of the closed region enclosed by the superstructure units 5 is larger than the radius R of the protection region because the actual superstructure unit 5 has a rectangular bottom surface. In this embodiment, the position cannot be uniquely determined by merely relying on the relative angles of the superstructure units 5, since the superstructure as a whole can be rotated around the centre of the circle without changing the relative angles. As shown in FIG. 5(D), taking an example of a superstructure consisting of four superstructure units 5, the position cannot be uniquely determined simply by virtue of the relative angles between the superstructure units 5, the relative angles of the superstructure units 5 in FIGS a, b, c are each 45 degrees, but the overall position of the superstructure is different. Thus, the present embodiment uniquely determines the overall position by the absolute position θ₁ of the first superstructure unit on the circle, and the relative positions θᵢ of the other units.

According to the solution of the present application, a plurality of low-frequency vibration-isolating superstructure units 5 are arranged on the flat plate 4, and the connecting lines of the centers of the second outer wall surfaces of the outer protective structures 1 in the superstructure units 5 form the closed region in a counterclockwise direction so as to form the vibration-isolating superstructure, and vibration isolation in a local region is achieved. This allows the superstructure to be applied to different flat plate structures such as composite materials, variable section flat plates and the like.

Further, in the superstructure, the second outer wall surface of the outer protective structure 1 of the superstructure unit 5 is fixed directly to the surface of the flat plate, and a contact part between the second outer wall surface and the flat plate does not move relatively.

According to a third aspect of the present application, a method of designing a low-frequency vibration-isolating superstructure according to an embodiment of the present application is illustrated for determining the number N of the superstructure units and the respective superstructure units θᵢ in the low-frequency vibration-isolating superstructure as described above, the method including;
Step S1: a frequency f of external vibration that needs to be isolated and a first order natural frequency f₁ of a superstructure unit 5 are acquired; a superstructure is disposed on one side of a flat plate 4, the length, width and height of the flat plate 4 are denoted as Lₚₕ, L_{pw}, Lₚₜ, respectively; the material density, Young's modulus and Poisson's ratio of the flat plate 4 are denoted as ρ_{b}, E_{b} and μ_{b}, respectively; a circular boundary of a protection region 6 of the low-frequency vibration-isolating superstructure is made as a circle of radius R; the material density, Young's modulus and Poisson's ratio of the superstructure unit 5 are denoted as ρ, E and μ, respectively;
Step S2: defining conditions for the volume of the low-frequency vibration-isolating superstructure are obtained, a minimum value L_{w}^{min} and a maximum value L_{w}^{max} of L_{w} are determined based on the defining conditions, L_{w} is initialized into (L_{w}^{min}+L_{w}^{max})/2; initial values of Lₜ and L_{g} are determined such that the initial values satisfy the following inequalities:

$$\{ \begin{matrix}0 < {L}_{g} < {L}_{t} / 2 \\ {L}_{t} < ( {L}_{w} - 2 {L}_{g} ) / 2\end{matrix}$$

H₀ is initialized, such that 0<H₀<L_{w}/2; the value of M is initialized to 1;
Step S3: based on the initial values of the structural parameters L_{w}, Lₜ, L_{g}, H₀, M and the material parameters of the superstructure unit (5), a finite element model of the superstructure unit (5) is established, a second outer wall surface of the superstructure unit 5 is set as a fixed boundary condition; the parameters L_{w}, Lₜ are optimized, the optimized parameters L_{w}, Lₜ make the first order natural frequency f₁ of the superstructure unit equal to f;
Step S4: the superstructure unit 5 is modified based on the optimized parameters L_{w}, Lₜ, intensity checking is performed on the superstructure unit 5;
Step S5: size parameters and material parameters of the flat plate 4 of the low-frequency vibration-isolating superstructure are acquired, a finite element model is established according to the size and material parameters, several vibration sources are set according to actual operating conditions at a vibration source region, and an excitation force with a frequency f is applied to simulate an actual vibration source; the radius of the closed circular region defined by the center points of the bottom surfaces of the low-frequency vibration-isolating superstructure units 5 is made as Rₘ, which is greater than or equal to R+L_{w}/2; a number N of the superstructure units 5 is initialized, N satisfying Nₘᵢₙ≤N≤Nₘₐₓ, wherein N, Nₘᵢₙ and Nₘₐₓ are all positive integers; an initial value of N is taken as Nₘᵢₙ; the lower limit of Nₘᵢₙ is 3; the upper limit of Nₘₐₓ is

$$[ \frac{π}{arc tan ( \frac{{H}_{0}}{2 {R}_{m} - {L}_{w}} )} ] ,$$

[ ] represents a rounding function;
Step S6: several vibration sources are set according to actual operating conditions in the vibration source region, and an excitation force with a frequency f is applied; the N modified superstructure units 5 are arranged into a circular closed region of radius Rₘ taking the center points of the bottom surfaces as the reference points; the first superstructure unit is made on a connecting line of either vibration source and the circle center by the initial value of θ₁; all the superstructure units 5 are evenly distributed over the boundary of the closed region of radius Rₘ by the initial values of the remaining polar angles θᵢ;
Step S7: a variable η=|w/w₀| is calculated by traversing all positive integers in the interval [Nₘᵢₙ, Nₘₐₓ], the value of N that minimizes η is found; wherein w represents an average out-of-plane displacement of the protection region when the flat plate 4 has the superstructure units 5, w₀ represents the average out-of-plane displacement of the protection region when the flat plate 4 has no superstructure units 5;
Step S8: if N=Nₘₐₓ, Nₘᵢₙ=[(Nₘᵢₙ+Nₘₐₓ)/2] and Nₘₐₓ=[(3Nₘₐₓ−Nₘᵢₙ)/2] are made, Step S7 is proceeded; and
if N<Nₘₐₓ, step S9 is proceeded; [ ] denotes a rounding function; and
Step S9: position angles θᵢ, of the N superstructure units 5 are determined, 1<i<N, wherein: θ₁ has an optimization interval of [0°, 360°], θ₂˜θ_{N} have an optimization interval of

$$[ 2 atan ( \frac{{H}_{0}}{2 R - {L}_{w}} ) , 360 ° - 2 N atan ( \frac{{H}_{0}}{2 R - {L}_{w}} ) ] ,$$

the constraint condition is

$${\sum }_{i = 2}^{N} {θ}_{i} \leq 360 ° - 2 atan ( \frac{{H}_{0}}{2 R - {L}_{w}} ) ,$$

and the optimization objective is to minimize the variable η.

The vibration isolation effect of the superstructure can be enhanced by optimization of the number and positions of the superstructure units. By optimizing the number, the vibration response of the protection region 6 under excitation is reduced, and at the same time, the number of the superstructure units 5 is reduced as much as possible, so that the additional mass of the flat plate 4 is reduced. By limiting θᵢ in position optimization, the overlap and interference of the superstructure units in the optimization process are avoided.

In this embodiment, the number N of the superstructure units 5 and the determined position θᵢ of each superstructure unit 5 in the low-frequency vibration-isolating superstructure capable of local region vibration isolation of the flat plate 4 are obtained after optimization.

In step S3, the fixed boundary condition is such that no movement of the second outer wall surface occurs.

The step S3 that the parameters L_{w}, Lₜ are optimized, the optimized parameters L_{w}, Lₜ make the first order natural frequency f₁ of the superstructure unit equal to f includes:
Step S301: an optimization interval of the parameter L_{w} is determined as [L_{w}^{min}, L_{w}^{max}], the optimization objective is to minimize obj=(f₁−f)²; the initial values of L_{w}^{min}, L_{w}^{max} are determined according to the operating conditions;
Step S302: if the obtained parameter L_{w} after optimization is equal to L_{w}^{max} then M is set to M+1, Step S301 is proceeded; if the obtained parameter L_{w} after optimization is equal to L_{w}^{min}, Lₜ, L_{g} and H₀ are redetermined, the following inequalities are satisfied:

$$\{ \begin{matrix}0 < {L}_{g} < {L}_{t} / 2 \\ {L}_{t} < ( {L}_{w} - 2 {L}_{g} ) / 2\end{matrix}$$

$$0 < {H}_{0} < {L}_{w} / 2$$

step S301 is proceeded;
if the obtained parameter L_{w} after optimization satisfies L_{w}∈(L_{w}^{min}, L_{w}^{max}), the parameter L_{w} is updated to the value of the optimized parameter L_{w}, step S303 is proceeded; and
Step S303: an optimization interval of the parameter Lₜ is determined as [2L_{g}, (L_{w}−2L_{g})/2], endpoint values are excluded here; the optimization objective is to minimize obj=(f₁−f)², the parameter Lₜ is updated to the value of the optimized parameter Lₜ.

In this embodiment, L_{w}^{max} can be large if space conditions allow, and L_{w}^{min} can be small if machining precision allows.

In this embodiment, the value of the first-order natural frequency f₁ of the superstructure unit 5 in relation to the size of the unit structure can be calculated by the finite element method, so that, in step S302, for example, the bending structure 3 of the superstructure unit 5 is changed by changing M, the superstructure unit 5 at present is different from the previous superstructure unit, so that a different parameter L_{w} is obtained. For example, Lₜ, L_{g}, and H₀ are changed, and the superstructure unit structure is also changed, resulting in different parameters L_{w}. After obtaining the different parameters L_{w}, and iterating to step S301, it is possible to determine the optimization interval [L_{w}^{min}, L_{w}^{max}] for the parameter L_{w} that differs in value from the previous optimization interval.

By adjusting and optimizing the unit structural parameters M, L_{w}, Lₜ, L_{g} and H₀, a superstructure unit 5 with a first order natural frequency f₁ equal to the elastic wave frequency f to be isolated is obtained. The multiple unit structural parameters increase the designability of the resonance frequency of the superstructure unit 5, enabling different frequency requirements such as low-frequency, high frequency, etc. to be met.

In step S4, wherein the superstructure unit 5 is strength checked to ensure that it does not fail due to inner mass block amplitude and stress concentration at the bending structure under service dynamic load excitation or impact loading.

In step S5, wherein the initial value of Nₘᵢₙ is taken as 3 and the initial value of Nₘₐₓ is taken as

$$[ \frac{π}{6 arc tan ( \frac{{H}_{0}}{2 {R}_{m} - {L}_{w}} )} ] .$$

The method of the present application is further described in accordance with another embodiment of the present application.

The frequency of vibration to be isolated in this embodiment is f=50 Hz, the first order natural frequency of the superstructure unit 5 is denoted as f₁, the length and width of the flat plate 4 to be vibration-isolated are Lₚₕ=400 mm and L_{pw}=400 mm, respectively, and the thickness is Lₚₜ=1 mm. The radius of the protection region 6 is noted as R=48 mm. The material used is aluminium, the density, Young's modulus and Poisson's ratio are ρ=2700 kg/m³, E=70 GPa and μ=0.33, respectively. The minimum value L_{w}^{min}=10 mm and maximum value L_{w}^{max}=20 mm of L_{w} are determined according to the limits on the volume of the structure in actual engineering and its initial value is determined to be 15 mm; the initial values of Lₜ, L_{g} and H₀ are determined to be 3 mm, 1 mm and 5 mm, respectively, and the initial value of N is taken to be 1. The finite element model of the superstructure unit 5 is built from its initial values of structural parameters, the bottom surface is set as the fixed boundary condition. The parameter L_{w} is optimized by the Nelder-Mead algorithm with an optimization interval of [10 mm, 20 mm] and an optimization objective of minimizing obj=(f₁−50 Hz)². The first order natural frequency of the superstructure unit 5 when M=9, L_{w}=17.31 mm is obtained after 9 optimizations. Optimization of the parameter Lₜ is performed by the Nelder-Mead algorithm with an optimization interval of [2 mm, 7.66 mm] and an optimization objective of minimizing obj=(f₁−50 Hz)², and the first order natural frequency f₁=49.987 Hz of the superstructure unit when Lₜ=2.89 mm is obtained, its first order mode is as shown in FIG. 6(A).

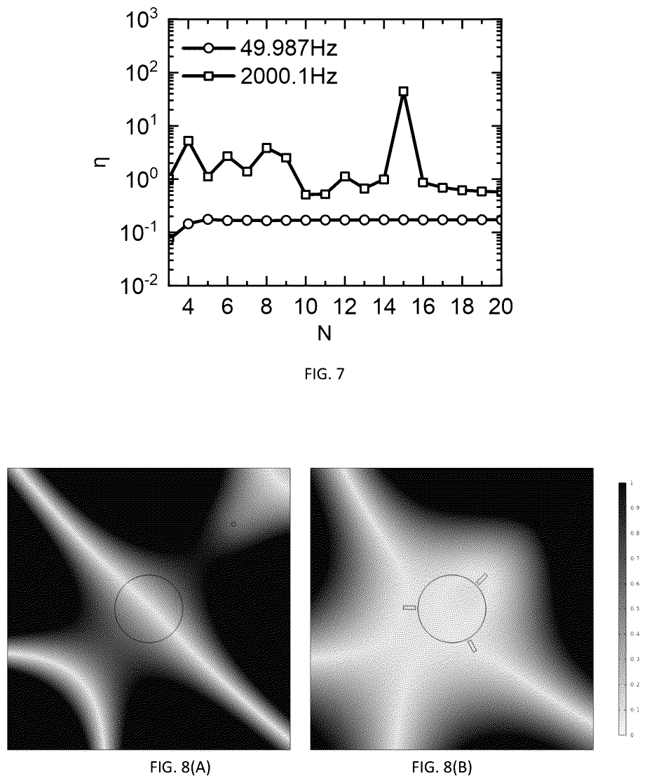

A finite element model of the flat plate 4 is established according to its structural parameters, and the protection region 6 is a circular region of R=48 mm, with the center of the circle located at the center of the plane of the plate. Taking the center of the circle as the pole point, and taking the direction of one side length of the flat plate 4 as the polar axis, a planar rectangular coordinate system is established, one point source is set at the coordinates (120\sqrt{2},225°), and a unit excitation force with a frequency of f=49.987 Hz is applied. The 3 optimized superstructure units 5 are placed along a circular boundary of Rₘ=60 mm to form a superstructure with one unit facing the vibration source and the other units evenly distributed. By traversing all positive integers in the interval [3, 20], a curve of the variable η=|w/w₀| changing with the number N is examined, and the curve is shown by a line with small circles in FIG. 7, wherein n is a minimum of 0.072 when the number is 3. The position angles θᵢ of the 3 superstructure units are optimized by the Nelder-Mead algorithm, where i denotes the unit serial number, taking 1, 2, 3. The optimized interval for θ₁ is [0°, 360°] and the initial value is 225°. The optimized interval for θ₂˜θ₆ is [5.58°, 348.85°], and the initial values are 120°. The constraint condition is Σᵢ₌₂^{N}θᵢ≤354.42°. The protection region η is only 0.060 when θ₁=224.77°, θ₂=133.80°, and θ₃=120.03° by optimization, its out-of-plane displacement magnitude field is as shown in FIGS. 8 (A)-8 (B). By comparing the field maps, the designed superstructure achieves flat plate local region vibration isolation.

The method of the present application is further described in accordance with another embodiment of the present application.

The frequency of vibration to be isolated in this embodiment is f=2000 Hz, the first order natural frequency of the superstructure unit 5 is denoted as f₁, the length and width of the flat plate to be vibration-isolated are Lₚₕ=400 mm and L_{pw}=400 mm, respectively, and the thickness is Lₚₜ=1 mm. The radius of the protection region is denoted as R=48 mm. The material used is aluminium, the density, Young's modulus and Poisson's ratio are ρ=2700 kg/m³, E=70 GPa and μ=0.33, respectively. The minimum value L_{w}^{min}=10 mm and maximum value L_{w}^{max}=20 mm of L_{w} are determined according to the limits on the volume of the structure in actual engineering and its initial value is determined to be 15 mm; the initial values of Lₜ, L_{g} and H₀ are determined to be 3 mm, 1 mm and 5 mm, respectively, and the initial value of N is taken to be 1. The finite element model of the superstructure unit 5 is built from its initial values of structural parameters, the bottom surface is set as the fixed boundary condition. The parameter L_{w} is optimized by the Nelder-Mead algorithm with an optimization interval of [10 mm, 20 mm] and an optimization objective of minimizing obj=(f₁−2000 Hz)². The first order natural frequency of the superstructure unit 5 when M=1, L_{w}=14.53 mm is obtained as 1996.2 Hz after one optimization. Optimization of the parameter Lₜ is performed by the Nelder-Mead algorithm with an optimization interval of [2 mm, 6.27 mm] and an optimization objective of minimizing obj=(f₁−2000 Hz)², and the first order natural frequency f_{1=2000.1} Hz of the superstructure unit when Lₜ=3.06 mm is obtained, its first order mode is as shown in FIG. 6(B).

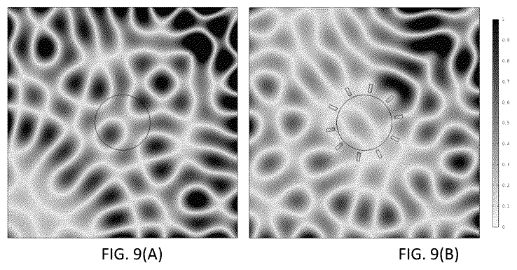

A finite element model of the flat plate 4 is established according to its structural parameters, and the protection region 6 is a circular region of R=48 mm, with the center of the circle located at the center of the plane of the plate. Taking the center of the circle as the pole point, and taking the direction of one side length of the flat plate 4 as the polar axis, a planar rectangular coordinate system is established, one point source is set at the coordinates (120\sqrt{2},225°), and a unit excitation force with a frequency of f=2000.1 Hz is applied. The 3 optimized superstructure units 5 are placed along a circular boundary of Rₘ=60 mm to form a superstructure with one unit facing the vibration source and the other units evenly distributed. By traversing all positive integers in the interval [3, 20], a curve of the variable η=|w/w₀| changing with the number N is examined, and the curve is shown by a line with small squares in FIG. 7, wherein η is a minimum of 0.515 when the number is 10. The position angles θᵢ of the 10 superstructure units are optimized by the Nelder-Mead algorithm, where i denotes the unit serial number, taking 1, 2, 3 . . . 10. The optimized interval for θ₁ is [0°, 360°] and the initial value is 225°. The optimized interval for θ₂˜θ₆ is [5.43°, 311.14°], and the initial values are 36°. The constraint condition is Σᵢ₌₂^{N}θᵢ≤354.57°. The protection region η is only 0.482 when θ₁=222.68°, θ₂=27.25°, θ₃=37.25°, θ₄=37.25°, θ₅=37.25°, θ₆=31.38°, θ₇=37.25°, θ₈=34.78°, θ₉=37.25°, and θ₁₀=37.25° by optimization, its out-of-plane displacement magnitude field is as shown in FIGS. 9 (A)-9 (B). By comparing the field maps, the designed superstructure achieves flat plate local region vibration isolation.

It should be noted that the embodiments and the features of the embodiments in the present application can be combined with each other without conflict.

The above embodiments are only used to illustrate the technical solutions of the present application, but not to limit them; although the present application has been described in detail with reference to the foregoing embodiments, it will be understood by those skilled in the art that modifications may be made to the solutions of the foregoing embodiments or equivalents may be substituted for some of the features thereof; such modifications or substitutions do not materially depart from the spirit and scope of the embodiments of the present application.

1. A low-frequency vibration-isolating superstructure unit, comprising:
an outer protective structure (1), an inner mass block (2) and a bending structure (3);
the outer protective structure (1) is a concave structure and one side with an opening is placed vertically; the inner mass block (2) and the bending structure (3) are arranged inside a cavity defined by three inner walls and an opening of the outer protective structure (1); an outer wall of the outer protective structure (1) have three surfaces, each outer wall surface has one inner wall surface corresponding thereto, the two surfaces of the outer wall parallel to each other are respectively a first outer wall surface and a second outer wall surface, when the side of the outer protective structure (1) with the opening is placed vertically, the first outer wall surface is an upper wall surface and the second outer wall surface is a lower wall surface; an outer wall surface perpendicular to the first outer wall surface and the second outer wall surface is a third outer wall surface;
the inner mass block (2) is arranged on the side of the outer protective structure (1) close to the vertical inner wall, the inner mass block (2) is connected with the bending structure (3) at the top close to the side with the opening of the concave structure; and
the bending structure (3) is arranged on a side of the outer protective structure (1) close to the opening, the bending structure (3) comprises [symbol] shaped structures (18) vertically spliced, a top vertical beam (12) and a top transverse beam (13), M>1; the [symbol] shaped structure (18) is composed of a first vertical beam (8) and a second vertical beam (9) of the same size, and a first transverse beam (10) and a second transverse beam (11) of the same size, two ends of each of the first transverse beam (10) and the second transverse beam (11) are respectively a head and a tail, wherein one end close to the opening side of the concave structure is a head; the first transverse beam (10) is located below the second transverse beam (11), the first transverse beam (10) is flush with both end surfaces of the second transverse beam (11); both the first transverse beam (10) and the second transverse beam (11) are straight beams with equal cross sections, and the cross sections are rectangular; the first transverse beam (10) has a first bottom surface (14) and a second bottom surface (15) in a horizontal direction, and the second transverse beam (11) has a third bottom surface (16) and a fourth bottom surface (17) in a horizontal direction, the first bottom surface (14), the second bottom surface (15), the third bottom surface (16), and the fourth bottom surface (17) are parallel to each other; an upper bottom surface of the first vertical beam (8) is fixed to a head of the first bottom surface (14) of the first transverse beam (10), and a lower bottom surface of the first vertical beam (8) is fixed to a head of the fourth bottom surface (17) of the second transverse beam of another [symbol] shaped structure or connected to an edge of the bottom inner wall of the outer protective structure (1) when the [symbol] shaped structure is the bottommost [symbol] shaped structure; a lower bottom surface of the second vertical beam (9) is fixed to a tail of the first bottom surface (15) of the first transverse beam (10); an upper bottom surface of the second vertical beam (9) is fixed to a tail of the third bottom surface (16) of the second transverse beam (11); a lower bottom surface of the top vertical beam (12) is fixed to a head of the fourth bottom surface (17) of the second transverse beam (11) of a top [symbol] shaped structure, and an upper bottom surface of the top vertical beam (12) is fixed to a head of a lower bottom surface of the top transverse beam (13); the top transverse beam (13) extends to the inside of the outer protective structure (1) and is connected to the top of the inner mass block (2), the upper bottom surface of the top transverse beam (13) is aligned with the top of the inner mass block (2).

2. The low-frequency vibration-isolating superstructure unit according to claim 1, wherein the bottom surface of the superstructure unit (5) is rectangular, and a side perpendicular to the plane of the opening is a long side, and a side parallel to the plane of the opening is a short side; the superstructure unit (5) constructs a right-hand Cartesian coordinate system with a vertex in the rectangular bottom surface away from the opening side as an origin, with a length direction of a short side of the bottom surface across the origin as an X-axis direction, with a length direction of a long side of the bottom surface across the origin as a Y-axis direction, and with a length direction of a third side across the origin point as a Z-axis direction; the superstructure unit (5) has a thickness H₀, each outer wall surface has a length L_{w}, the distance between the corresponding inner wall surface and the outer wall surface of each group is Lₜ; a gap of the inner mass block (2) with the inner wall surface of the outer protective structure (1) is L_{g}, a length of the inner mass block (2) along the y-axis direction is (L_{w}−Lₜ−2L_{g})/2, a length along the z-axis direction is L_{w}−2Lₜ−2L_{g}; the length of each of the first vertical beam, the second vertical beam and the top vertical beam in the [symbol] shaped structure is (L_{w}−2Lₜ−L_{g})/(4M+2) along the y-axis and z-axis, the length of each of the first transverse beam and the second transverse beam in the [symbol] shaped structure (18) is (L_{w}−Lₜ−2L_{g})/2 along the y-axis and the length is (L_{w}−2Lₜ−L_{g})/(4M+2) along the z-axis, and the length of the top transverse beam is (L_{w}−Lₜ)/2 along the y-axis and the length is (L_{w}−2Lₜ−L_{g})/(4M+2) along the z-axis.

3. The low-frequency vibration-isolating superstructure unit according to claim 1, wherein a rectangular channel is provided between the corresponding inner wall surface and the outer wall surface of each group, four surfaces of the rectangular channel form an outer protective structural wall with an outer adjacent surface thereof, and the thickness of the outer protective structural wall is L_{g}.

4. A low-frequency vibration-isolating superstructure, comprising N superstructure units (5) according to claim 1, wherein the N superstructure units (5) are disposed on one side of a flat plate (4); the flat plate (4) is divided into a protection region (6) and a vibration source region (7) according to actual operating conditions, and the region other than the protection region (6) of the flat plate (4) is the vibration source region (7); if the protection region (6) is circular, the circumference outside the protection region is a circular boundary; otherwise, the protection region is fitted to a polygon, a minimum covering circle of the protection region (6) that is able to cover a set of points S is determined, wherein the set of points S is a set of vertices of the polygon after the protection region (6) is fitted, and the circumference of the minimum covering circle is the circular boundary; a radius to which the circular boundary corresponds is a protection region radius R; the N superstructure units enclose the protection region (6), a first short side of the second outer wall surface of each superstructure unit (5) is parallel to a tangent to a point on the circular boundary of the protection region (6) closest to the first short side, the first short side is a short side of the second outer wall surface of the superstructure unit close to the opening side; the distance of the first short side of each superstructure unit (5) to the circle center of the circular boundary is greater than or equal to R; the distance of the short side of the second outer wall surface of each superstructure unit (5) away from the opening side to the circle center of the circular boundary is greater than the distance of the first short side to the circle center of the circular boundary; the N superstructure units (5) are N uniformly sized superstructure units, N>1.

5. The low-frequency vibration-isolating superstructure according to claim 4, wherein, after arranging N superstructure units (5) around the protection region (6), the N superstructure units (5) form a circular closed region on the flat plate (4), the closed region is composed of connecting lines of the centers of the second outer wall surfaces of the outer protective structures (1) in the superstructure units (5) in a counterclockwise or clockwise direction, wherein the connecting line is a circular arc; the radius R of the protection region is smaller than the radius Rₘ of the closed region.

6. The low-frequency vibration-isolating superstructure according to claim 5, wherein, a planar polar coordinate system is constructed by taking the circle center of the circular boundary of the protection region as the pole point and taking any direction as the polar axis, and the position of each superstructure unit (5) is represented by the bottom surface center point, the position of the superstructure unit (5) is uniquely determined by Rₘ and θᵢ, 1≤i≤N; Rₘ represents the radius of the closed region enclosed by the center points of the bottom surfaces of the superstructure units, and the value of the radius is determined based on the radius R of the protection region and the long-side size of the second outer wall surface; 01 represents the polar angle of the center point of the bottom surface of the first superstructure unit on a circle of radius Rₘ, and remaining polar angles θᵢ represent the angles between the ith superstructure unit and the i−1th superstructure unit; the value of θᵢ is determined according to the principle of maximization of vibration isolation efficiency; the first superstructure unit is any one of the N superstructure units, and the remaining superstructure units are sequentially numbered in a clockwise direction, or sequentially numbered in a counterclockwise direction from the first superstructure unit.

7. The low-frequency vibration-isolating superstructure according to claim 6, wherein in the superstructure, the second outer wall surface of the outer protective structure (1) of the superstructure unit (5) is fixed directly to the surface of the flat plate (4), and a contact part between the second outer wall surface and the flat plate (4) does not move relatively.

8. A method of designing a low-frequency vibration-isolating superstructure according to claim 4, comprising:
Step S1: acquiring a frequency f of external vibration that needs to be isolated, a first order natural frequency f₁ of a superstructure unit (5); disposing a superstructure on one side of a flat plate, denoting the length, width and height of the flat plate (4) as Lₚₕ, L_{pw}, Lₚₜ, respectively; denoting the material density, Young's modulus and Poisson's ratio of the flat plate (4) as ρ_{b}, E_{b} and μ_{b}, respectively; making a circular boundary of a protection region of the low-frequency vibration-isolating superstructure a circle of radius R; denoting the material density, Young's modulus and Poisson's ratio of the superstructure unit (5) as ρ, E and μ, respectively;
Step S2: obtaining defining conditions for the volume of the low-frequency vibration-isolating superstructure, determining a minimum value L_{w}^{min} and a maximum value L_{w}^{max} of L_{w} based on the defining conditions, initializing L_{w} into (L_{w}^{min}+L_{w}^{max})/2; determining initial values of Lₜ and L_{g} such that the initial values satisfy the following inequalities:
$$\{ \begin{matrix}0 < {L}_{g} < {L}_{t} / 2 \\ {L}_{t} < ( {L}_{w} - 2 {L}_{g} ) / 2\end{matrix}$$
initializing H₀, such that 0<H₀<L_{w}/2; initializing the value of M to 1;
Step S3: based on the initial values of the structural parameters L_{w}, Lₜ, L_{g}, H₀, M and the material parameters of the superstructure unit (5), establishing a finite element model of the superstructure unit (5), setting a second outer wall surface of the superstructure unit (5) as a fixed boundary condition; optimizing the parameters L_{w}, Lₜ, the optimized parameters L_{w}, Lₜ making the first order natural frequency f₁ of the superstructure unit equal to f;
Step S4: modifying the superstructure unit (5) based on the optimized parameters L_{w}, Lₜ, performing intensity checking on the superstructure unit (5);
Step S5: acquiring size parameters and material parameters of the flat plate of the low-frequency vibration-isolating superstructure, establishing a finite element model according to the size and material parameters, setting several vibration sources according to actual operating conditions at a vibration source region, and applying an excitation force with a frequency f to simulate an actual vibration source; making the radius of the closed circular region defined by the center points of the bottom surfaces of the low-frequency vibration-isolating superstructure units Rₘ, which is greater than or equal to R+L_{w}/2; initializing a number N of the superstructure units (5), N satisfying Nₘᵢₙ≤N≤Nₘₐₓ, wherein N, Nₘᵢₙ and Nₘₐₓ are all positive integers; taking an initial value of N as Nₘᵢₙ; the lower limit of Nₘᵢₙ being 3; the upper limit of Nₘₐₓ being
$$[ \frac{π}{arc tan ( \frac{{H}_{0}}{2 {R}_{m} - {L}_{w}} )} ] ,$$
[ ] representing a rounding function;
Step S6: setting several vibration sources according to actual operating conditions in the vibration source region, and applying an excitation force with a frequency f; arranging the N modified superstructure units (5) into a circular closed region of radius Rₘ taking the center points of the bottom surfaces as the reference points; making the first superstructure unit on a connecting line of either vibration source and the circle center by the initial value of θ₁; making all the superstructure units (5) evenly distributed over the boundary of the closed region of radius Rₘ by the initial values of the remaining polar angles θᵢ;
Step S7: calculating a variable η=|w/w₀| by traversing all positive integers in the interval [Nₘᵢₙ, Nₘₐₓ], finding the value of N that minimizes n; wherein w represents an average out-of-plane displacement of the protection region when the flat plate (4) has the superstructure units (5), w₀ represents the average out-of-plane displacement of the protection region when the flat plate (4) has no superstructure units (5);
Step S8: if N=Nₘₐₓ, making Nₘᵢₙ=[(Nₘᵢₙ+Nₘₐₓ)/2], Nₘₐₓ=[(3Nₘₐₓ−Nₘᵢₙ)/2],
proceeding to Step S7; and
if N<Nₘₐₓ, proceeding to step S9; [ ] denoting a rounding function; and
Step S9: determining position angles θᵢ, of the N superstructure units (5), 1<i<N, wherein: θ₁ has an optimization interval of [0°, 360°], θ₂˜θ_{N} have an optimization interval of
$$[ 2 atan ( \frac{{H}_{0}}{2 R - {L}_{w}} ) , 360 ° - 2 N atan ( \frac{{H}_{0}}{2 R - {L}_{w}} ) ] ,$$
the constraint condition is
$${\sum }_{i = 2}^{N} {θ}_{i} \leq 360 ° - 2 atan ( \frac{{H}_{0}}{2 R - {L}_{w}} ) ,$$
and the optimization objective is to minimize the variable η.

9. The method of designing a low-frequency vibration-isolating superstructure according to claim 8, wherein the step S3 of optimizing the parameters L_{w}, Lₜ, the optimized parameters L_{w}, Lₜ making the first order natural frequency f₁ of the superstructure unit equal to f comprises:
Step S301: determining an optimization interval of the parameter L_{w} as [L_{w}^{min}, L_{w}^{max}], the optimization objective being to minimize obj=(f₁−f)²; determining the initial values of L_{w}^{min},L_{w}^{max} according to the operating conditions;
Step S302: if the obtained parameter L_{w} after optimization is equal to L_{w}^{max} then setting M to M+1, proceeding to Step S301;
if the obtained parameter L_{w} after optimization is equal to L_{w}^{min}, re-determining Lₜ, L_{g} and H₀, satisfying the following inequalities:
$$\{ \begin{matrix}0 < {L}_{g} < {L}_{t} / 2 \\ {L}_{t} < ( {L}_{w} - 2 {L}_{g} ) / 2\end{matrix}$$
$$0 < {H}_{0} < {L}_{w} / 2$$
proceeding to step S301;
if the obtained parameter L_{w} after optimization satisfies L_{w}∈(L_{w}^{min},L_{w}^{max}), updating the parameter L_{w} to the value of the optimized parameter L_{w}, proceeding to step S303; and
Step S303: determining an optimization interval of the parameter Lₜ as [2L_{g}, (L_{w}−2L_{g})/2], excluding endpoint values here; the optimization objective being to minimize obj=(f₁−f)², updating the parameter Lₜ to the value of the optimized parameter Lₜ.

10. The method of designing a low-frequency vibration-isolating superstructure according to claim 9, wherein, in the step S5, the initial value of Nₘᵢₙ is taken to be 3 and the initial value of Nₘₐₓ is taken to be
$$[ \frac{π}{6 arc tan ( \frac{{H}_{0}}{2 {R}_{m} - {L}_{w}} )} ] .$$
